(19) United States
(12) Patent Application Publication
(10) Pub. No.: US 2009/0235971 A1
(43) Pub. Date: Sep. 24, 2009

(54) PHOTOACTIVE DEVICE WITH ORGANIC LAYERS

(76) Inventors: Martin Pfeiffer, Dresden (DE); Christian Uhrich, Dresden (DE); Annette Petrich, Dresden (DE); Rico Schuppel, Dresden (DE); Karl Leo, Dresden (DE); Peter Bauerle, Elchingen-1 (DE); Eduard Brier, Heidenheim (DE); Pinar Kilickiran, Esslingen (DE)

Correspondence Address: OSTROLENK FABER GERB & SOFFEN, 1180 AVENUE OF THE AMERICAS, NEW YORK, NY, 100368403, US

(21) Appl. No.: 12/253,630

(22) Filed: Oct. 17, 2008

Related U.S. Application Data
(63) Continuation of application No. 11/817,636, now abandoned.

(30) Foreign Application Priority Data
Mar. 4, 2005 (DE) 10 2005 010 979.9

(51) Int. Cl. H01L 31/042; H01L 31/00; H01L 31/18; B82B 1/00

(52) U.S. Cl. 136/244; 136/263; 427/74; 977/734; 977/742; 977/948

(57) ABSTRACT

The invention relates to a photoactive device with organic layers, especially a solar cell, with a layer arrangement having an electrode and a counterelectrode as well as a sequence of organic layers arranged between the electrode and the counterelectrode, wherein two layers bordering on one another are formed in a photoactive region encompassed by the sequence of organic layers, namely, an exciton-harvesting layer (EHL) and an exciton-separating layer (ESL); in which the exciton-harvesting layer (EHL) is a mixed layer containing an organic material (A) and at least one further organic material (B), in which (i) a lowest singlet excitation state for excitons (S₁^{A}) of the organic material (A) is energetically higher than a lowest singlet excitation state for excitons (S₁^{B}) of the further organic material (B), (ii) the further organic material (B) is chosen such that it transforms singlet excitons into triplet excitons with a quantum yield of at least approximately 20%, preferably of at least approximately 50% by an ISC mechanism (ISC—Inter-System-Crossing), and (iii) a lowest triplet excitation state for excitons (T₁^{B}) of the further organic material (B) is energetically higher than a lowest triplet excitation state for excitons (T₁^{A}) of the organic material (A); and wherein a donor-acceptor heterojunction is formed between the exciton-harvesting layer (EHL) and the exciton-separating layer (ESL) converting triplet excitons of the organic material (A) into free charge carrier pairs in the vicinity of the interface.

### CROSS REFERENCE TO RELATED APPLICATIONS

This is a continuation of U.S. patent application Ser. No. 11/817,636, filed Aug. 31, 2007, in the name of Martin PFEIFFER, Christian UHRICH, Annette PETRICH, Rico SCHÜPPEL, Karl LEO, Peter BÄUERLE, Eduard BRIER, and Pinar KILICKIRAN and entitled PHOTOACTIVE DEVICE WITH ORGANIC LAYERS, which was the National Stage of International Application No. PCT/DE2006/000409, filed 3 Mar. 2006, which claims priority of German Patent Application No. 10 2005 010 979.9, filed Mar. 4, 2005, which are herein incorporated by reference. The PCT International Application was published in the German Language.

The invention relates to a photoactive device with organic layers, especially a solar cell, with a layer arrangement having an electrode and a counterelectrode as well as a sequence of organic layers arranged between the electrode and the counterelectrode.

### BACKGROUND OF THE INVENTION

Since the demonstration of the first organic solar cell with a power efficiency in the percent range by Tang et al. 1986 (C. W. Tang et al., Appl. Phys. Lett., 48, 183 (1986)) organic materials have been intensively examined for various electronic and optoelectronic devices. Organic solar cells consist of a sequence of thin layers that typically have a thickness between 1 nm to 1 μm and of organic materials that are preferably vapor-deposited in a vacuum or are applied from a solution. The electrical contacting takes place as a rule by metallic layers and/or transparent conductive oxides (TCOs).

The advantage of such devices with an organic basis in comparison to the conventional devices with an inorganic basis, e.g., semiconductors such as silicon, gallium arsenide, are the partially extreme optical absorption coefficiencies of up to 2×10⁵ cm⁻¹, so that there is the possibility of producing very thin solar cells with a low expense for material and energy. Further technological aspects are the low costs, the possibility of producing flexible, large-area structural components on plastic foils, and the almost unlimited possibilities for variation in organic chemistry.

A solar cell converts light energy into electrical energy. In contrast to inorganic solar cells, in the case of organic solar cells free charge carriers are not directly produced by the light but rather excitons are formed at first, that is, electrically neutral excitation states, namely, bound electron-hole pairs. These excitons can only be separated by very high electrical fields or on suitable boundary surfaces. In organic solar cells sufficiently high fields are not available, so that all concepts that promise success for organic solar cells are based on the separation of excitons on photoactive interfaces (organic donor-acceptor interface—C. W. Tang, Appl. Phys. Lett., 48 (2), 183-185 (1986)) or a interface to an inorganic semiconductor (cf. B. O'Reagan et al., Nature 353, 737 (1991)). It is required for this that excitons that were generated in the volume of the organic material can defuse to this photoactive interface.

The recombination-poor diffusion of excitons to the active interface therefore plays a critical part in organic solar cells. Therefore, in order to make a contribution to the photocurrent in a good organic solar cell, the exciton diffusion length must be at least on the order of the typical penetration depth of light in order that the primary part of the light can be utilized. Organic crystals or thin layers that are perfect structurally and as regards the chemical purity absolutely meet this criterion. However, for large-area applications the use of monocrystalline organic materials is not possible and the production of multiple layers with sufficient structural perfection has been very difficult up to now.

Instead of enlarging the exciton diffusion length it is also possible to reduce the average distance to the next interface. Document WO 00/33396 described the formation of a so-called interpenetrating network: A layer contains a colloidally dissolved substance that is distributed in such a manner that a network forms over which charge carriers can flow (percolation mechanism). The task of light absorption is assumed in such a network either only by one of the components or also by both of them.

The advantage of such a mixed layer is that the generated excitons only have to travel a very short path until they reach a domain boundary, where they are separated. The transport of the electrons and of the holes to the respective contact takes place separately in the dissolved substance or in the remaining layer. Since the materials are in contact with each other throughout the mixed layer, it is decisive in this concept that the separated charges have a long lifetime on the particular material, and that closed percolation paths for both charge carrier sorts to the particular contact are present from each location. Degrees of efficiency of 2.5% were able to be achieved with this approach (C. J. Brabec et al., Advanced Functional Materials 11, 15 (2001)).

Further known approaches for realizing respectively improving the properties of organic solar cells are enumerated in the following:

One contact metal has a large and the other contact metal has a small work function, so that a Schottky barrier is formed with the organic layer (U.S. Pat. No. 4,127,738).

The active layer consists of an organic semiconductor in a gel or a binder (U.S. Pat. No. 3,844,843; U.S. Pat. No. 3,900,945; U.S. Pat. No. 4,175,981 and U.S. Pat. No. 4,175,982).

Production of a transport layer that contains small particles with a size of 0.01 to 50 μm that assume the charge carrier transport (U.S. Pat. No. 5,965,063).

One layer contains two or more types of organic pigments with different spectral characteristics (JP 04024970).

One layer contains a pigment that produces the charge carriers, and additionally a material that removes the charge carriers (JP 07142751).

Polymer-based solar cells containing carbon particles as electron acceptors (U.S. Pat. No. 5,986,206).

Doping of the previously mentioned mixed systems for improving the transport properties in multilayer solar cells (cf. DE 102 09 789).

Stacking of individual solar cells on top of each other so that a so-called tandem cell is formed (U.S. Pat. No. 4,461,992; U.S. Pat. No. 6,198,091; U.S. Pat. No. 6,198,092).

Tandem cells can be further improved by using p-i-n structures with doped transport layers with a large band gap (DE 103 13 232).

The doping of organic materials is known from document U.S. Pat. No. 5,093,698. The admixture of an acceptor-like or of a donor-like doping substance elevates the equilibrium charge carrier concentration in the layer and increases the conductivity. According to the comments in document U.S. Pat. No. 5,093,698 the doped layers are used as injection layers on the interface to the contact materials or electrode materials in electroluminescent devices. Similar doping approaches are also analogously purposeful for solar cells.

In spite of the advantages described above in interpenetrating networks a critical point is present in the fact that in the mixed layer closed transport paths to the particular contacts must be present for electrodes as well as for holes. Moreover, since each of the individual materials only fill out a part of the mixed layer, the transport properties for the charge carriers clearly deteriorate in comparison to the pure layers.

If interpenetrating networks are to be avoided, the critical parameter for organic solar cells is the diffusion length for excitons L_{D}, that can be calculated from the lifetime of excitons τ and the diffusion constant D according to L_{D}=\sqrt{D_{T}}. For singlet excitons the diffusion length of approximately 0.1 to 10 ns is usually very small, e.g., 3 to 10 nm on account of their short lifetime (cf. M. Hoffmann et al., J. of Fluorescence, 5 (2), 217 (1995) or P. Peumans et al., J. Appl. Phys., 93, 3693 (2003). For triplet excitons the diffusion length can be distinctly greater, since they have lifetimes that are higher by several orders of magnitude of approximately 1 μs to approximately 10 ms (cf. C. Adachi et al., Appl. Phys. Lett. 79, 2082, (2001)).

During excitation with light, singlet excitons are generated at first since the photons of the light do not have any spin and the total spin remains preserved during the excitation process. In special material classes, but in particular in phosphorescent complexes of heavy metals such as Ir or Pt, singlet excitons are converted very rapidly and efficiently into triplet excitons. This mechanism is designated as Inter-System-Crossing (ISC).

Document DE 103 13 232 describes an organic solar cell in which materials with an elevated ISC probability are used as a component of an organic heterojunction. Even further solar cells (cf. P. Peumans et al., J. Appl. Phys., 79 (1), 126 (2001)) are partially based of the fact that excitations in fullerene C₆₀ pass with a high probability into the triplet state, where they have high diffusion lengths of approximately 40 nm (P. Peumans et al., J. Appl. Phys., 93, 3693 (2003)).

However, the direct use of such materials with elevated ISC probability as component of an organic heterojunction entails various problems. Typical phosphorescent metal complexes as well as fullerene C₆₀ have only very small absorption coefficients in the range of the lowest excitation energy. For the phosphorescent metal complexes this is due to the fact that the lowest excitation state consists of an excitation of an electron of the metal in the organic ligand (MLCT—metal to ligand charge transfer) and that such junctions have small oscillator strengths on account of the small spatial overlapping of the participating orbitals, as results by way of example from FIG. 1. FIG. 1 shows the chemical structure of a typical iridium complex as well as a graphic representation of a phosphorescence emission in the red spectral range and of an absorption spectrum of a 20 nm-thick layer on quartz glass. The lowest-energetic absorption band around 550 nm is only very weakly pronounced.

For fullerene C₆₀ the optical excitation of the lowest excitation state is prohibited by the symmetry. Therefore, an efficient absorption takes place only for higher excitation states. The excitation energy then relaxes very quickly into the lowest state, which means an energy loss for the solar cell.

Materials that favor the mechanism of the inter-system crossing, e.g., on account of heavy metals, therefore unavoidably also have shorter lifetimes of the triplet state, e.g. only 1 μs for Ir(ppy)₃ (cf. C. Adachi et al., Appl. Phys. Lett., 77 (6), 904-906 (2000)). This value can still decrease on account of non-radiating recombination channels in aggregates by several orders of magnitude (cf. M. A. Baldo et al., Appl. Phys. Lett., 75 (1), 4-6 (1999)), since the recombination contains for its part an inter-system crossing. This has a negative effect on the diffusion lengths of the triplet excitons: Accordingly, diffusion lengths for triplet excitons of up to 140 nm were reported for the non-phosphorescent material Alq₃ (M. A. Baldo et al., Phys. Rev. B 60, 14422 (1999)). Similar high values are not known for phosphorescent systems.

### TASK OF THE INVENTION

The invention has the task of creating a photoactive device with organic layers in which the efficiency of the conversion of energy is improved.

### SUMMARY OF THE INVENTION

This task is solved in accordance with the invention by a photoactive device in accordance with independent claim 1. Advantageous embodiments of the invention constitute subject matter of dependent subclaims.

The invention comprises the concept of providing a photoactive device with organic layers, especially a solar cell, with a layer arrangement having an electrode and a counterelectrode as well as a sequence of organic layers that is arranged between the electrode and the counterelectrode, wherein:
two layers bordering on one another are formed within a photoactive region encompassed by the sequence of organic layers, namely, an exciton-harvesting layer, the exciton-harvesting layer (EHL) and an exciton-separating layer (ESL);
the exciton-harvesting layer (EHL) is a mixed layer containing an organic material (A) and at least a further organic material (B), in which:
   a lowest singlet excitation state for excitons (S₁^{A}) of the organic material (A) is energetically higher than a lowest singlet excitation state for excitons (S₁^{B}) of the further organic material (B),
   the further organic material (B) is chosen in such a way that it transforms singlet excitons into triplet excitons with a quantum yield of at least approximately 20%, preferably of at least approximately 50%, by an ISC mechanism (ISC—Inter-System-Crossing) and
   a lowest triplet excitation state for excitons (T₁^{B}) of the further organic material (B) is energetically higher than a lowest triplet excitation state for excitons (T₁^{A}) of the organic material (A); and
a donor-acceptor heterojunction is formed between the exciton-harvesting layer (EHL) and the exciton-separating layer (ESL) converting triplet excitons of the organic material (A) into free charge carrier pairs in the vicinity of the interface

The exciton-harvesting layer (EHL), in which triplet excitons are formed on account of light absorption, is formed as a mixture of an organic material A and at least one further organic material B. After the excitation of a singlet exciton on the organic material A the excitation energy is transferred to the further organic material B, which requires that its lowest singlet excitation state (S₁^{B}) is energetically lower than the lowest singlet excitation state (S₁^{A}) of the organic material A. The further organic material B is selected in such a manner that the inter-system crossing is favored, so that on the further organic material B singlet excitons are converted with a probability of at least 50% into triplet excitons on the further organic material B. Then, a back transfer of the triplet excitons from the further organic material B onto the organic material A takes place, which requires that the lowest triplet excitation state T₁^{A} on the organic material A is energetically lower than the lowest triplet excitation state T₁^{B} on the further organic material B.

In this manner long-lived triplet excitons are generated on the organic material A with a high quantum yield that defuse to an interface to the exciton-separating layer (ESL), the interface between the exciton-harvesting layer (EHL) and the exciton-separating layer (ESL) being designed in such a manner that the long-lived triplet excitons are separated at the interface to the exciton-harvesting layer (EHL) into a charge carrier on the exciton-harvesting layer (EHL) and into an inversely charged charge carrier on the exciton-separating layer (ESL).

The photoactive interface can thus be built in such a manner that either holes are formed in the exciton-harvesting layer (EHL) and electrons in the exciton-separating layer (ESL) or vice versa. The charge carriers formed in this manner in the exciton-harvesting layer (EHL) are designated in the following as “photo-generated charge carriers”. The transport of the photo-generated charge carriers can take place within the exciton-harvesting layer either preferably on the organic material A or on the further organic material B. If the photo-generated charge carriers are transported in an advantageous embodiment of the invention on the organic material A or in the same manner on the organic material A and on the further organic material B, the further organic material B is neither obligatorily necessary for charge carrier transport nor for exciton transport, which is explained in detail below using exemplary embodiment 4. Therefore, a very small concentration of the further organic material B is sufficient, that only has to fulfill the condition that a large part of the singlet excitation states on the organic material A must reach the surrounding of the further organic material B during their lifetime in order to be converted there into triplet excitons. That means that an average distance of the molecules or clusters of the further organic material B in the organic material A must be less than the diffusion length of the singlet excitons in the organic material A, which is typically approximately 3 to 20 nm.

In another purposeful embodiment of the invention, the photo-generated charge carriers in the exciton-harvesting layer (EHL) are preferably transported on the further organic material B, which is explained in detail below using the first to third exemplary embodiments, then the concentration of the further organic material B in organic material A must be above a percolation limit in order to make closed transport paths available for charge carriers. The concentration here is advantageously greater than approximately 15%, preferably greater than approximately 30%.

In contrast to the suggestion in document DE 103 13 232, in the device in accordance with the invention the diffusion of triplet excitons on the material with elevated ISC probability is not utilized but rather the further organic material B with an efficient inter-system crossing mechanism serves as a type of “catalyst” in order to generate long-lived triplet excitons in the organic material A acting as host material.

The layer arrangement in accordance with the invention can be used in various embodiments of the invention and solar cells with an M-i-M, p-i-n, M-i-p or M-i-n structure, in which the following abbreviations apply: M—metal, p—p-doped organic or inorganic semiconductor, n—n-doped organic or inorganic semiconductor, and i—intrinsically conductive system of organic layers (cf. e.g., J. Drechsel et al., Org. Electron., (4), 175 (2004); Maennig et al., Appl. Phys. A 79, 1-14 (2004)).

A preferred embodiment of the invention provides the use of the layer arrangement in accordance with the invention in a tandem cell where tandem cells as such have been described by Peumans et al. (cf. P. Peumans et al., J. Appl. Phys., 93 (7), 3693-3723 (2003); U.S. Pat. No. 4,461,922; U.S. Pat. No. 6,198,091 or U.S. Pat. No. 6,198,092). Even the use in tandem cells of two or more stacked M-i-M, p-i-n, M-i-p or M-i-n diodes can be provided (cf. DE 10 2004 014046 A1; J. Drechsel et al., Thin Solid Films, 451452, 515-517 (2004)).

A layer can be selected as exciton-separating layer ESL that serves exclusively for the separation of excitons and for charge carrier transport, as is provided below in exemplary embodiment 1. However, it can also be a layer that in addition absorbs light and is suitable for converting the excitation states being produced here in the volume or on one of its interfaces into free charge carrier pairs. For example, the exciton-separating layer can comprise a photoactive bulk heterojunction as is provided below in exemplary embodiment 5 (cf. G. Yu et al., Science, 270 (5243), 1789 (1995); WO 00/33396), or it can be a layer that makes possible the diffusion of singlet or triplet excitons to the interface to the exciton-harvesting layer, as is provided below in exemplary embodiment 4.

Further advantageous embodiments of the invention result from the dependent subclaims.

A purposeful further development of the invention provides that the following applies for one or more organic materials (Ci; i≧1) from which the exciton-separating layer (ESL) is formed and for the organic material (A) and the at least one further organic material (B) from which the exciton-harvesting layer (EHL) is formed:
for at least one of the organic materials (Ci) a highest occupied molecular orbital (HOMO) is energetically higher than a respective highest occupied molecular orbital (HOMO) of the organic material (A) and of the at least one further organic material (B); and
a respective lowest unoccupied molecular orbital (LUMO) is energetically higher for all organic materials (Ci) than a respective lowest unoccupied molecular orbital (LUMO) of the organic material (A) or of the at least one further organic material (B).

A preferred further development of the invention can provide that the following applies for one or more organic materials (Ci; i≧1) from which the exciton-separating layer (ESL) is formed and for the organic material (A) and the at least one further organic material (B) from which the exciton-harvesting layer (EHL) is formed:
for at least one of the organic materials (Ci) a lowest unoccupied molecular orbital (LUMO) is energetically lower than a respective lowest unoccupied molecular orbital (LUMO) of the organic material (A) of the at least one further organic material (B); and
a respective highest occupied molecular orbital (HOMO) is energetically lower for all organic materials (Ci) than a respective highest occupied molecular orbital (HOMO) of the organic material (A) or of the at least one further organic material (B).

A purposeful embodiment of the invention can provide that a mass concentration of the organic material (A) in the exciton-harvesting layer (EHL) produced as mixed layer is greater than approximately 30%, preferably greater than approximately 60% and more preferably greater than approximately 90%.

An advantageous embodiment provides that the lowest unoccupied molecular orbital (LUMO) of the organic material (A) is energetically lower or at the most approximately 0.1 eV higher than the lowest unoccupied molecular orbital (LUMO) of the at least one further organic material (B).

A preferred further development of the invention provides that the highest occupied molecular orbital (HOMO) of the organic material (A) is energetically higher or at the most approximately 0.1 eV lower than the highest occupied molecular orbital (HOMO) of the at least one further organic material (B).

A preferred further development of the invention provides that a mass concentration of the organic material (A) as well as a mass concentration of the further organic material (B) in the exciton-harvesting layer (EHL) produced as a mixed layer is greater than approximately 15%, preferably greater than approximately 30%.

A purposeful embodiment of the invention can provide that a lowest unoccupied molecular orbital (LUMO) of the organic material (B) is energetically lower or at the most approximately 0.1 eV higher than the lowest unoccupied molecular orbital (LUMO) of the organic material (A).

An advantageous embodiment of the invention provides that a highest occupied molecular orbital (HOMO) of the at least one further organic material (B) is energetically higher or at the most approximately 0.1 eV lower than the highest occupied molecular orbital (HOMO) of the organic material (A).

A preferred further development of the invention provides that a triplet transport layer (TTL) of one or several organic materials is arranged between the exciton-harvesting layer (EHL) and the exciton-separating layer (ESL), the energy of a lowest triplet excitation state of the triplet transport layer being less than or equal to the energy of the lowest triplet excitation state of the organic material (A) in the exciton-harvesting layer (EHL) produced as mixed layer.

A preferred further development of the invention provides that a highest occupied molecular orbital (HOMO) of the triplet transport layer (TTL) is energetically equal to or is lower than the respective highest occupied molecular orbital (HOMO) of the organic material (A) or of the at least one further organic material in the exciton-harvesting layer (EHL) produced as mixed layer.

A purposeful embodiment of the invention can provide that a lowest unoccupied molecular orbital (LUMO) of the triplet transport layer (TTL) is energetically equal to or is higher than the lowest unoccupied molecular orbital (LUMO) of the organic material (A) or of the at least one further organic material in the exciton-harvesting layer (EHL) produced as mixed layer.

An advantageous embodiment of the invention provides that in the at least one further organic material (B) an energy difference between the lowest singlet excitation state for excitons (S₁^{B}) and the lowest triplet excitation state for excitons (T₁^{B}) is less than approximately 0.5 eV, preferably less than approximately 0.3 eV.

A preferred further development of the invention provides that the at least one further organic material (B) is from one of the following material classes:
fullerene or carbon nanotubes, in particular C₆₀, C₇₀ or C₈₄ and their derivatives;
metallo-organic compounds, in particular those whose lowest excitation state comprises at least partially an excitation of an electron from the metal to the ligand (MLCT—metal-to-ligand charge transfer) or from the ligand to the metal (LMCT—ligand-to-metal charge transfer); and
phosphorescent materials with a phosphorescence quantum yield greater than approximately 0.1%, preferably greater than approximately 1% in dilute solution.

A preferred further development of the invention provides that the metallo-organic compound comprises a heavy metal with an atomic number greater than 21, preferably greater than 39.

A purposeful embodiment of the invention can provide that the metallo-organic compound comprises a metal from the following group of metals: Ru, Pd, Ag, Cd, In, Sn, Ta, W, Re, Os, Ir, Pt, Au, Hg, Ti, Pb, La, Ce, Pr, Nd, Sm, Eu, Gd, Th, Er, Tm, Yb or Lu, preferably Ru, Rh, Re, Os, Ir or Pt.

An advantageous embodiment of the invention provides that the organic material (A) in the exciton-harvesting layer (EHL) produced as mixed layer is an oligothiophene derivative, a perylene derivative, especially a derivative of perylene tetracarboxylic acid dianhydride, perylene tetracarboxylic acid diimide or perylene tetracarboxylic acid bisimidazole, or a phthalocyanine.

A preferred further development of the invention provides that the exciton-separating layer (ESL) is formed as a light-absorbing layer producing singlet- and/or triplet excitation states, in which produced singlet and/or triplet excitation states diffuse to the interface between the exciton-harvesting layer (EHL) and the exciton-separating layer (ESL), where they can be converted into charge carrier pairs.

A preferred further development of the invention provides that the exciton-separating layer (ESL) is a mixed layer containing several organic materials, in which:
a lowest singlet excitation state for excitons of one of the several organic materials is energetically higher than a lowest singlet excitation state for excitons of a further one of the several organic materials;
the further organic material is formed in such a manner that it converts singlet excitons into triplet excitons with a quantum yield of at least 20%, preferably at least 50% by means of an ISC mechanism (ISC—Inter-System-Crossing);
a lowest triplet excitation state for excitons of the further organic material is energetically lower than a lowest triplet excitation state for excitons of the one organic material.

A purposeful embodiment of the invention can provide that a photoactive donor-acceptor bulk-heterojunction is formed in the exciton-separating layer (ESL) produced as mixed layer by means of the one organic material and of the at least one further organic material.

An advantageous embodiment of the invention provides that an interface of the exciton-harvesting layer (EHL), that faces away from the interface with the exciton-separating layer (ESL)/the triplet transport layer (TTL), is a triplet blocking layer (TBL) in which energetically lowest energetic triplet excitation states are energetically higher than lowest energetic triplet excitation states in the exciton-harvesting layer (EHL).

A preferred further development of the invention provides that the contact and/or the countercontact are semi-transparent or transparent.

A preferred further development of the invention provides that that a p-doped layer (M-i-p device) is arranged between the contact and the photoactive region.

A purposeful embodiment of the invention can provide that an n-doped layer (M-i-n device or n-i-p device) is arranged between the countercontact and the photoactive region.

An advantageous embodiment of the invention provides that one or more layers in the organic region are deposited by thermal vaporization in a high vacuum or the vaporizing of organic materials into an inert carrier gas that transports the organic materials to a substrate (organic vapor phase deposition).

A preferred further development of the invention provides that one or more layers in the organic region are deposited from a liquid solution, especially by spin-coating, application with a doctor blade and/or printing.

A preferred further development of the invention provides that the exciton-harvesting layer (EHL) has a thickness between approximately 5 nm and approximately 200 nm.

A purposeful embodiment of the invention can provide that the exciton-harvesting layer (EHL), the exciton-separating layer (ESL) and/or the triplet transport layer (TTL) are formed from a donor-acceptor-donor oligomer or from an acceptor-donor-acceptor oligomer.

### BRIEF DESCRIPTION OF THE DRAWINGS

The invention is explained in detail in the following referring to figures of drawings, in which:

FIG. 1 shows the chemical structure of a typical iridium complex as well as a graphic representation of a phosphorescence emission in the red spectral range and of an absorption spectrum of a 20 nm-thick layer on quartz glass;

FIG. 2 shows the structural formula of DCV3T;

FIG. 3 shows the chemical structure of MeOTPD (above; MeO designates a methoxy group) and 4P-TPD (below);

FIG. 4 shows a schematic representation with energy levels for explaining the method of functioning of a photoactive device in accordance with a first exemplary embodiment with an exciton-harvesting layer of a mixture of DCV3T and C₆₀ and an exciton-separating layer of MeOTPD;

FIG. 5 shows a graphic representation of absorption and photo luminescence values as a function of the wavelength for a DCV3T individual layer with a thickness of 20 nm, a DCV3T:C₆₀ mixed layer with a thickness ratio of 20 nm:27 nm and a C₆₀ individual layer with a thickness of 27 nm;

FIG. 6 shows a graphic representation of a change of the transmission at a measuring temperature of 10K for a DCV3T layer with a thickness of 20 nm (circles) and a DCV3T:C₆₀ mixed layer with a thickness ratio of 20 nm:27 nm (squares) after excitation with an Ar(+) laser at 514 nm with a power density of 30 mW/cm⁻²;

FIG. 7 shows a current-voltage characteristics under illumination with simulated sunlight with an intensity of 127 mW/cm² and without illumination for a photoactive device according to a second exemplary embodiment with a 30 nm-thick mixed layer of DCV3T and C₆₀ (1:2) as exciton-harvesting layer and tetramethoxytetraphenylbenzidine (MeOTPD) as exciton-separating layer;

FIG. 8 shows a graphic representation of the wave-length dependency of the external quantum efficiency (EQE), shown by a solid line, of a photoactive device with the layer sequence ITO/C₆₀/DCV3T/MeOTPD/p-doped MeOTPD/gold and shows the course of the absorption coefficient of DCV3T as a line in dots and dashes and the absorption coefficient of C₆₀ as a dotted line;

FIG. 9 shows a schematic representation with energy levels for explaining the method of functioning of a photoactive device in accordance with a sixth exemplary embodiment; and

FIG. 10 shows structural formulas for a class of compounds that can be used as organic material A in an exciton-harvesting layer, in which a group R can be hydrogen, an alkyl group or a cyano group and the group X in the oligothiophene chain can be one of the groups a) to d) or another homocyclic or heterocyclic compound with conjugated π-electron system.

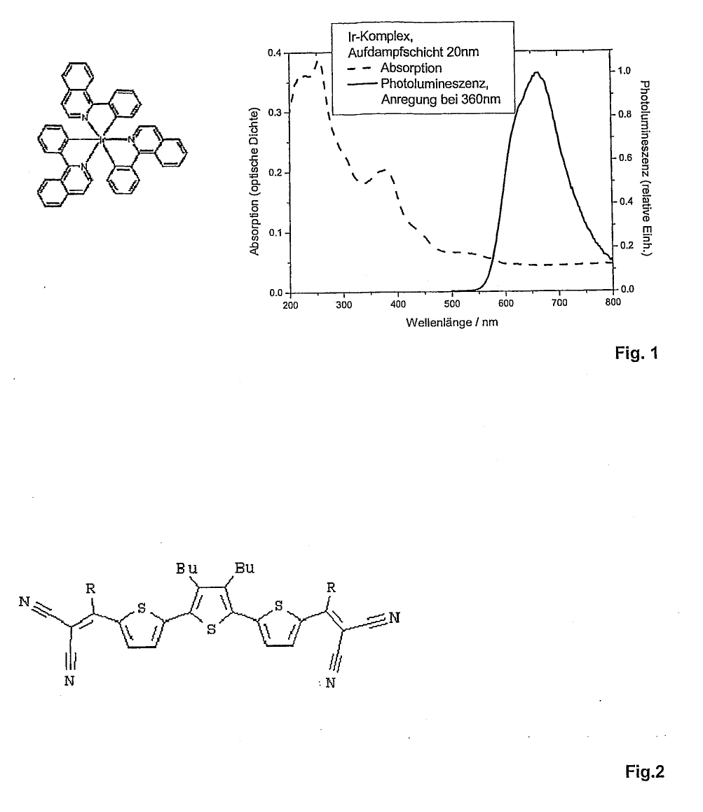

### DESCRIPTION OF PREFERRED EMBODIMENTS

In the following various exemplary embodiments for a photoactive device with organic layers are described with reference made to FIG. 2 to 10 that can be realized in particular as a solar cell.

In the various embodiments of the device, a layer arrangement is provided that has an electrode and a counterelectrode as well as a sequence of organic layers arranged between the electrode and the counterelectrode. Two adjacent layers, namely, an exciton-harvesting layer (EHL) and an exciton-separating layer (ESL) are formed in a photoactive region encompassed by the sequence of organic layers. The exciton-harvesting layer (EHL) is a mixed layer containing an organic material A and a further organic material B. In the mixed layer the lowest singlet excitation state for excitons (S₁^{A}) of the organic material (A) is higher energetically than a lowest singlet excitation state for excitons (S₁^{B}) of the further organic material B. The further organic material B converts singlet excitons with a high quantum yield of at least approximately 20%, preferably at least approximately 50% by means of an ISC mechanism (ISC—Inter-System-Crossing) into triplet excitons. Furthermore, the mixed layer is produced in such a manner that a lowest triplet excitation state for excitons (T₁^{B}) of the further organic material B is higher energetically than a lowest triplet excitation state for excitons (T₁^{A}) of the organic material A so that the triplet exciton formed on the material B can be transferred with high probability to the material A. A donor-acceptor heterojunction that can separate triplet excitons of organic material A into free charge carrier pairs is formed by an interface between the exciton-harvesting layer (EHL) and the exciton-separating layer (ESL).

### First Exemplary Embodiment

The following layer sequence is provided in a first exemplary embodiment: ITO/DCV3T*C₆₀/MeOTPD/p-doped MeOTPD/gold. ITO designates a transparent ground contact here of indium-tin oxide and C₆₀ the Buckminster fullerene.

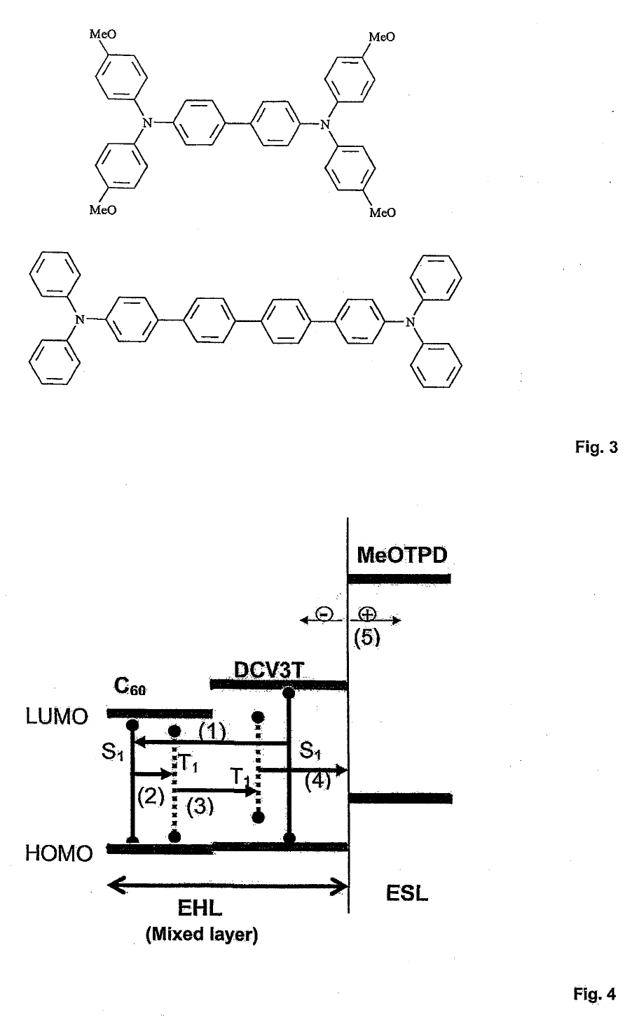

The structure of the other materials is shown in FIG. 2 and FIG. 3. FIG. 2 shows the structural formula of DCV3T. The group R in DCV3T is a hydrogen atom but can also be a cyano group (TCV3T, cf. T. M. Pappenfus et al., Org. Lett. 5 (9), 1535-1538 (2003)) or an alkyl group in derivatives. FIG. 3 shows the chemical structure of MeOTPD (above in FIG. 3; MeO designates a methoxy group) and 4P-TPD (below in FIG. 3).

The p-doping takes place e.g., by mixed vapor deposition with perfluorinated tetracyano quinodimethane (F₄-TCNQ). In this first exemplary embodiment the exciton-harvesting layer consists of DCV3T (organic material A) and C₆₀ (further organic material B) and the exciton-separating layer of MeOTPD.

FIG. 4 shows a schematic representation for explaining the method of functioning of a device according to the first exemplary embodiment with an exciton-harvesting layer of a mixture of DCV3T and C₆₀ and with an exciton-separating layer of MeOTPD. The following steps of the process are represented:
(0) Excitation of a singlet exciton of DCV3T by light absorption;
(1) Transfer of the singlet excitation state from DCV3T to C₆₀;
(2) Inter-system crossing on C₆₀;
(3) Transfer of the triplet excitation state from C₆₀ to DCV3T;
(4) Diffusion of the triplet excitation state on DCV3T to the interface between the exciton-harvesting layer and the exciton-separating layer;
(4) Separation of the triplet excitation state into an electron in the exciton-harvesting layer, namely, on the lowest unoccupied molecular orbital (LUMO) of C₆₀ and a hole in the exciton layer, namely, on the highest occupied molecular orbital (HOMO) of MeOTPD.

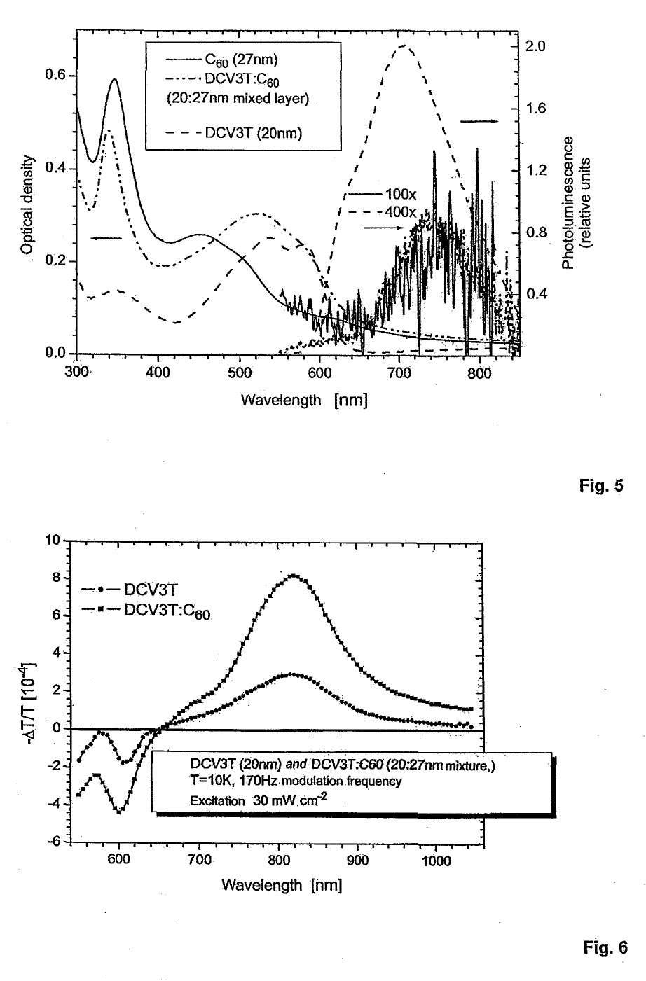

Singlet excitons are first generated on DCV3T by light absorption. The excitation energy is very rapidly transferred to C₆₀. The demonstration for this is the fact that pure layers of DCV3T display efficient fluorescence with an average decay time of approximately 200 ps. This fluorescence is reduced by an admixture of C₆₀ to below 1% of the original intensity, which is shown in FIG. 5. It results from the above that a quenching process takes place on a time scale of less than 1 ps.

It is known that singlet excitons on C₆₀ are converted with high probability into triplet excitons, in which according to Peumans (cf. P. Peumans et al., J. Appl. Phys., 93, 3693 (2003)) η_{ISC}=96% at room temperature applies. The triplet excitons are transferred back onto DCV3T in the following step. This is shown by a comparison of the photo-induced absorption of pure DCV3T layer with the mixed layer of DCV3T and C₆₀, as is shown in FIG. 6. In both instances an additional “photo-induced” absorption with the same spectrum is shown after pulsed excitation, which can be traced back to the excitation of triplet excitons into higher states. However, the measuring signal is strengthened by a factor of three on account of the admixture of C₆₀, which shows that the population of the triplet excitation state on DCV3T is increased on account of the above-described mechanism.

The triplet excitons on DCV3T formed in this manner can now diffuse to the interface with MeOTPD where they can be separated into free holes on MeOTPD and free electrons on C₆₀. In the embodiment selected the lowest unoccupied molecular orbital (LUMO) of the further organic material, namely, C₆₀, is lower than the lowest unoccupied molecular orbital (LUMO) of the organic material A, namely, DCV3T, so that the charge transport of electrons takes place on the further organic material B. This results in the requirement that the further organic material B must be present in sufficient concentration for making closed percolation paths available.

### Second Exemplary Embodiment

In a second exemplary embodiment the following layer sequence is provided for the photoactive device: ITO/C₆₀/DCV3T*C₆₀/MeOTPD/p-doped MeOTPD/gold.

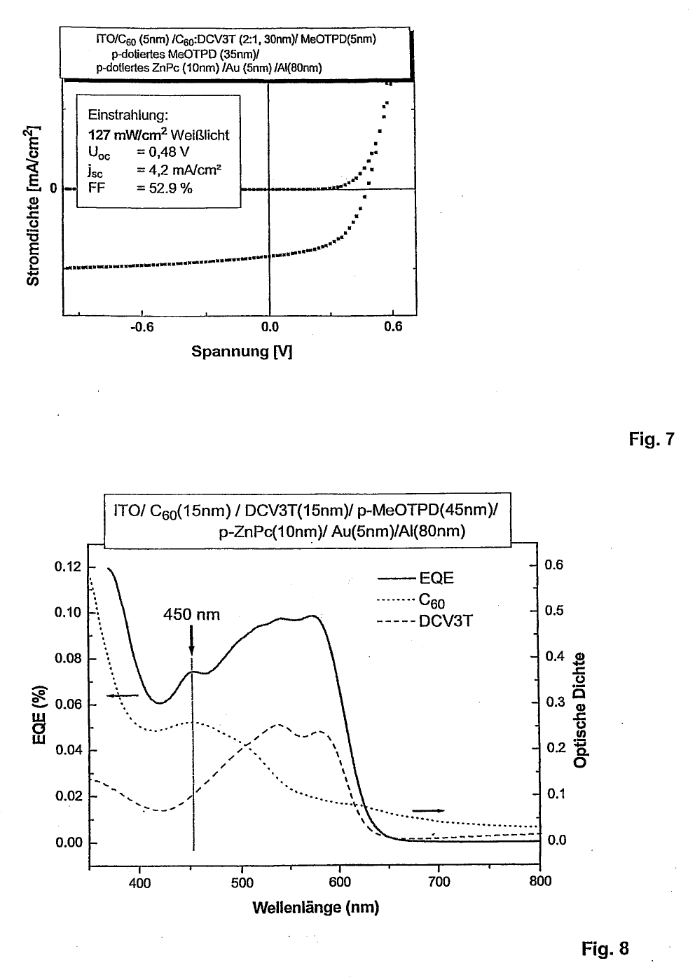

In distinction to the first exemplary embodiment an additional pure C₆₀ layer is arranged here as a triplet blocking layer (TBL) between the exciton-harvesting layer and the ITO electrode. The method of functioning of the device corresponds to that of the device in accordance with the first exemplary embodiment. The triplet blocking layer fulfils the function of preventing triplet excitons that diffuse in the direction of the ITO electrode from being quenched there. Instead, the triplet excitons are reflected on C₆₀ and have another chance to reach the interface to the exciton-harvesting layer. FIG. 7 shows a current-voltage characteristics under illumination with simulated sunlight with an intensity of 127 mW/cm² and without illumination for a device in accordance with the second exemplary embodiment with a 30 nm-thick mixed layer of DCV3T and C₆₀ (1:2) as exciton-harvesting layer and tetramethoxy-tetraphenyl-benzidine (MeOTPD) as exciton-separating layer. The layer sequence is indicated in detail in FIG. 7, in which p-MeOTPD and p-ZnPc are p-doped layers of MeOTPD/zinc phthalocyanine with F₄-TCNQ serving as acceptor-type doping agent.

### Third Exemplary Embodiment

In a third exemplary embodiment the following layer sequence is provided for the photoactive device: ITO/C₆₀/DCV3T*C₆₀/DCV3T/MeOTPD/p-doped MeOTPD/gold.

In distinction to the second exemplary embodiment an additional pure layer (TTL—triplet transport layer) of DCV3T (organic material A of the exciton-harvesting layer) is introduced between the exciton-harvesting layer and the exciton-separating layer. The triplet excitons, that are formed in the exciton-harvesting layer, must additionally diffuse here through the DCV3T layer until they can be separated at the interface to the exciton-separating layer into holes on MeOTPD and electrons on DCV3T.

The fact that the transfer of triplet excitons takes place from C₆₀ onto DCV3T and the diffusion of the transferred triplet excitons onto DCV3T is proven by the signal clearly coming from C₆₀ in the external quantum efficiency of a solar cell with the layer sequence ITO/C₆₀/DCV3T/MeOTPD/p-doped MeOTPD/gold (cf. FIG. 8). In the third exemplary embodiment the diffusion of singlet excitons on DCV3T to the exciton-separating layer is additionally utilized for charge carrier generation.

FIG. 8 shows a graphic representation of the wavelength dependency of the external quantum efficiency (EQE), that is shown by solid line 80, of a photoactive device with the layer sequence ITO/C₆₀/DCV3T/MeOTPD/p-doped MeOTPD/gold. The course of the absorption coefficient of DCV3T is represented as line 81 in dashes. The absorption coefficient of C₆₀ is shown with the aid of dotted line 82. The external quantum efficiency has a peak at a wavelength of 450 nm that can be traced back to the absorption of the C₆₀.

The device in accordance with the third embodiment has the further advantage over the devices according to the first and second embodiments that the LUMO of the additional pure DCV3T layer is higher than the LUMO of C₆₀. Therefore, charge carrier pairs with greater free energy are formed on the interface to the exciton-harvesting layer and the device achieves a higher photovoltage.

### Fourth Exemplary Embodiment

In a fourth exemplary embodiment the following layer sequence is provided for the photoactive device: ITO/C₆₀/DCV3T*C₆₀/ZnPc/p-doped MeOTPD/gold.

In distinction to the second exemplary embodiment zinc phthalocyanine (ZnPc) is used as exciton-separating layer, that has a strong absorption in the visible spectral range. The excitons photogenerated in ZnPc can diffuse to the exciton-harvesting layer and be separated there into free electrons on C₆₀ and free holes on ZnPc so that here the exciton-harvesting layer makes a contribution to the generation of the photocurrent as well.

### Fifth Exemplary Embodiment

In a fifth exemplary embodiment the following layer sequence is provided for the photoactive device: ITO/C₆₀/DCV3T*C₆₀/4P-TPD*C₆₀ (1:3)/MeOTPD/p-doped MeOTPD/gold.

A mixed layer of 4P-TPD (cf. FIG. 3) and C₆₀ is provided as exciton-separating layer. The method of functioning of the device in accordance with the fifth embodiment corresponds to that of the device in accordance with the second embodiment.

Furthermore, 4P-TPD and C₆₀ form a bulk heterojunction in the exciton-separating layer that can convert excitons formed on one of the two materials into charge carrier pairs in its entire volume, namely, holes on 4P-TPD and electrons on C₆₀. Thus, the exciton-separating layer additionally contributes here to the generation of photocurrent. Alternatively, the material 4P-TPD can be replaced in this embodiment by other hole transport materials with stronger absorption, e.g., a phthalocyanine or an oligothiophene derivative.

### Sixth Exemplary Embodiment

In a sixth exemplary embodiment the following layer sequence is provided for the photoactive device: ITO/TCV3T*C₆₀/MeOTPD/p-doped MeOTPD/gold.

The method of functioning of the device in accordance with the sixth embodiment corresponds to that of the device in accordance with the first embodiment with the distinction that the charge separation on the exciton-separating layer results in the generation of electrons on TCV3T, which is the organic material A of the exciton-harvesting layer, and holes on MeOTPD since the organic material A has a lower LUMO here than the further organic material B, namely, C₆₀. Therefore, the transport of triplet excitons and of charge carriers, namely, of electrons, takes place on the organic material A whereas the further organic material B serves exclusively to support the ISC. Consequently, the further organic material B does not have to make any closed percolation paths available in the exciton-harvesting layer, and a concentration between approximately 0.1 and 10% is sufficient. This is an advantage for the generation of photocurrent since the organic material A typically has the stronger absorption.

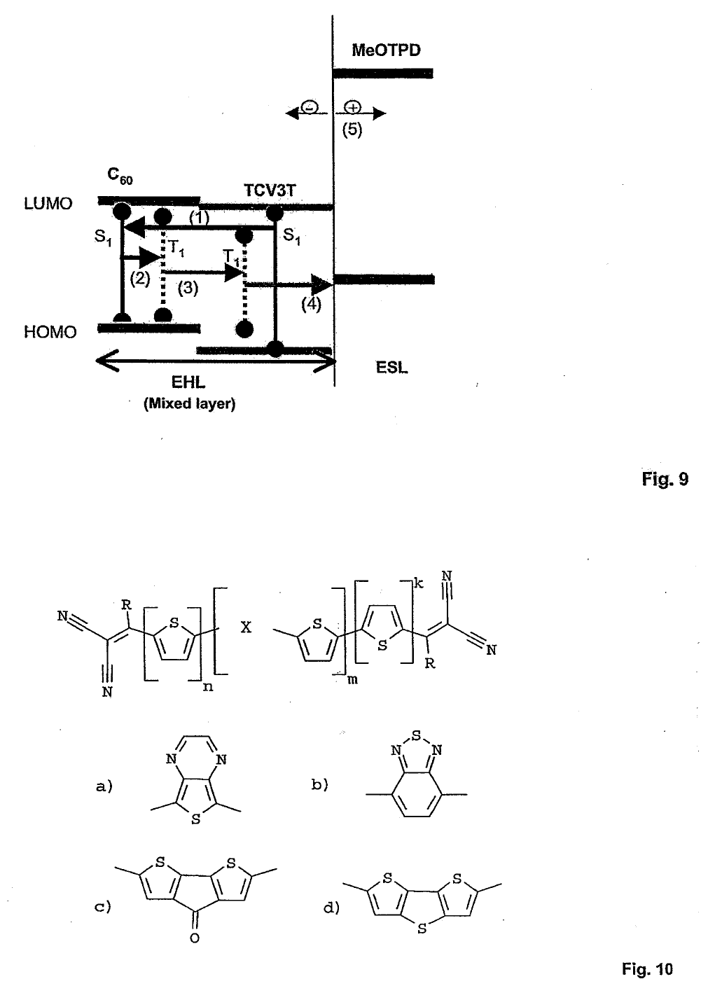

FIG. 9 shows a schematic representation of the method of functioning of a photoactive device in accordance with the sixth exemplary embodiment. The following partial processes are represented:
(0) Excitation of a singlet exciton on TCV3T by light absorption;
(1) Transfer of the singlet excitation state from TCV3T to C₆₀;
(2) Inter-system crossing on C₆₀;
(3) Transfer of the triplet excitation state from C₆₀ to TCV3T;
(4) Diffusion of the triplet excitation state on TCV3T to the interface between the exciton-harvesting layer and the exciton-separating layer;
(5) Separation of the triplet excitation state into an electron in the exciton-harvesting layer, namely, on the LUMO of TCV3T, and into a hole in the exciton-separating layer, namely on the highest occupied molecular orbital (HOMO) of MeOTPD).

In photoactive devices with a layer sequence in accordance with one of the above exemplary embodiments a thiophene derivative with a structural formula according to FIG. 10 or a perylene derivative can be alternatively used as organic material A in the exciton-harvesting layer. FIG. 10 shows structural formulas for a class of compounds that can be used as organic material A in the exciton-harvesting layer. The group R can be hydrogen here, an alky group or a cyano group. The X group in the oligothiophene chain can be one of the groups a) to d) or another homocyclic or heterocyclic compound with conjugated 7′-electron system. Furthermore, a donor-acceptor-donor oligomer or an acceptor-donor-acceptor oligomer as disclosed in the simultaneously submitted PCT application with the title “Organisches photoaktives Bauelement (Organic Photoactive Device)”, whose content is integrated in this respect here by reference, or other donor-acceptor co-oligomers can be used for the organic material A in the exciton-harvesting layer as well as for the material of TTL and of the exciton-separating layer.

In the above exemplary embodiments the exciton-harvesting layer has the function, in addition to the absorption of light and the transport of excitons, of transporting photo-generated electrons. It therefore preferably has an electron mobility of at least 5×10⁻⁷ cm²/V. However, the device can also be inversely conceived in such a manner that photo-generated holes are transported in the exciton-harvesting layer. In this case materials for the structure according to FIG. 10 with a suitably selected group R can also be used as organic material A in the exciton-harvesting layer, which group is preferably hydrogen or an alkyl group but not electron-attracting groups such as CN. A suitable material is, e.g., DCV5T, a compound with R═H, n=0, m=0 and k=5.

A heavy metal complex can be used as further organic material B, e.g., a platinum complex (PtK) or an iridium complex (IrK) with a phosphorescence in the infrared spectral range. This results in the following layer sequence for a further exemplary embodiment: ITO/C₆₀/DCV5T*IrK/p-doped MeOTPD/gold. The exciton-harvesting layer is formed here by a mixture of DCV5T and IrK and C₆₀ forms the exciton-separating layer. Depending on the energetic position of the HOMO of IrK, the hole transport in the mixed layer of IrK with DCV5T takes place primarily on DCV5T if the highest occupied molecular orbital (HOMO) of IrK is lower than the highest occupied molecular orbital (HOMO) of DCV5T, or it takes place primarily on IrK if the highest occupied molecular orbital (HOMO) of IrK is higher than the highest occupied molecular orbital (HOMO) of DCV5T. In the first-cited instance a very slight concentration of IrK in DCV5T of approximately 0.1 to approximately 10% suffices, analogously to the considerations about the concentration of C₆₀ in TCV3T in the sixth exemplary embodiment. In the last-cited instance IrK must be present in the mixed layer in sufficient concentration, namely, with at least 15%, preferably with at least 30% so that a efficient hole transport on IrK can take place. An advantageous embodiment is also present if the highest occupied molecular orbital (HOMO) of IrK is maximally 0.1 eV higher than the highest occupied molecular orbital (HOMO) of DCV5T so that IrK forms a flat trap site for holes in DCV5T. Since the holes can be readily freed again from the trap sites by thermal energy, the transport of holes can take place on DCV5T and here too a very slight concentration of IrK in DCV5T between approximately 0.1 and approximately 10% is sufficient.

FIG. 5 shows measured values for absorption and photoluminescence as a function of the wavelength. For a DCV3T individual layer with a thickness of 20 nm, the absorption course 10 and the course of the photoluminescence 11 are represented as dashed lines. For a DCV3T:C₆₀ mixed layer formed by mixed vapor deposition with a thickness ratio of 20 nm:27 nm the absorption spectrum 20 and the photoluminescence spectrum 21 are represented as lines in dots and dashes. Furthermore, the absorption spectrum 30 and the photoluminescence spectrum 31 for a C₆₀ individual unit with a thickness of 27 nm are shown as a solid line.

The luminescence of the individual layer of DCV3T is extinguished at an excitation wavelength of 530 nm by the presence of C₆₀ in the DCV3T:C₆₀ mixed layer. A residual luminescence of the mixed layer at an excitation wavelength of 530 nm that is represented with a factor of 100 results at an excitation wavelength of 512 nm from the weak fluorescence of C₆₀, which results from a comparison with the measured values for the C₆₀ individual layer, that are multiplied by a factor of 400. The occurrence of the C₆₀ fluorescence even at the excitation of DCV3T shows that the singlet excitation energy is transferred from DCV3T onto C₆₀.

FIG. 6 shows the results of a measuring of the so-called “photo-induced absorption” at a measuring temperature of 10K for a DCV3T layer with a thickness of 20 nm (circles) and for a DCV3T:C₆₀ mixed layer with a thickness ratio of 20 nm:27 nm (squares) after excitation with an Ar(+) laser at 514 nm with a power density of 30 mW/cm⁻². During the measurings of the “photo-induced absorption” a sample is exposed to a periodically modulated illumination. In the present instance this was realized by an Ar ion laser directed through a rotating chopper wheel onto the sample. This “pump beam” thus results in a periodically varied excitation of the sample and therefore in a corresponding oscillating population density of excitation states (excitons).

At the same time a measuring beam of constant intensity is directed onto the sample and the transmission measured by a photodetector on the other side of the sample. Since excited molecules have another absorption spectrum than molecules in the ground state, the transmission probability of the measuring beam also oscillates now with the oscillation of the excitation density. Even if this transmission change ΔT is only in a range of approximately 10⁻⁴ of the total transmission T, the relevant signal can be filtered out at the chopper frequency by lock-in technology. Accordingly, in FIG. 6 the transmission change is represented normalized to the transmission (ΔT/T) as a function of the wavelength of the measuring beam at a chopper frequency of 170 Hz. The modulation of the wavelength of the measuring beam was realized by the combination of a halogen lamp with a grating monochromator.

For positive values of a transmission change below a wavelength of 660 nm the bleaching of the ground state (ground state bleaching) can be recognized. The negative transmission change, namely, additional absorption of the layer after the excitation, in a wide spectral range of 820 nm, can be traced to a triplet excitation state on DCV3T. The lifetime τ of the triplet excitation state is determined as τ=25 μs (from variation of the modulation frequency).

In the mixed layer the spectrum of the photo-induced absorption does not change in comparison to the pure DCV3T layer; likewise, the lifetime of the observed excitation is unchanged. However, the measured signal is greater by a factor of 3 in comparison to the individual layer: The size of the observed signal is decisively determined for small frequencies (ωτ<<1) by the product of lifetime and population of the state (cf., e.g., Dellepiane et al., Phys. Rev. B, 48, 7850 (1993); Epshtein et al., Phys. Rev. B, 63, 125206 (2001)). In the case of an unchanged lifetime the observed behavior accordingly allows an increased population of the triplet state on DCV3T, brought about by C₆₀ in accordance with the mechanism represented in FIG. 4, to be concluded.

The features of the invention disclosed in the previous description, the claims and the drawings can be significant individually as well as in any combination for the realization of the invention in its various embodiments.

1. A photoactive device with organic layers, especially a solar cell, with a layer arrangement having an electrode and a counterelectrode as well as a sequence of organic layers arranged between the electrode and the counterelectrode, in which:
two layers bordering on one another are formed in a photoactive region encompassed by the sequence of organic layers, namely, an exciton-harvesting layer (EHL—Electron Harvesting Layer) and an exciton-separating layer (ESL—Electron Separating Layer);
the exciton-harvesting layer (EHL) is a mixed layer containing an organic material (A) and at least a further organic material (B), in which:
a lowest singlet excitation state for excitons (S₁^{A}) of the organic material (A) is energetically higher than a lowest singlet excitation state for excitons (S₁^{B}) of the further organic material (B),
the further organic material (B) is chosen in such a way that it transforms singlet excitons into triplet excitons with a quantum yield of at least approximately 20%, preferably of at least approximately 50%, by an ISC mechanism (ISC—Inter-System-Crossing), and
a lowest triplet excitation state for excitons (T₁^{B}) of the further organic material (B) is energetically higher than a lowest triplet excitation state for excitons (T₁^{A}) of the organic material (A); and
a donor-acceptor heterojunction is formed between the exciton-harvesting layer (EHL) and the exciton-separating layer (ESL) converting triplet excitons of the organic material (A) into free charge carrier pairs in the vicinity of the interface.

2. The device according to claim 1, wherein the following applies for one or more organic materials (Ci; i≧1) from which the exciton-separating layer (ESL) is formed and for the organic material (A) and the at least one further organic material (B) from which the exciton-harvesting layer (EHL) is formed:
for at least one of the organic materials (Ci) a highest occupied molecular orbital (HOMO) is energetically higher than a respective highest occupied molecular orbital (HOMO) of the organic material (A) and of the at least one further organic material (B); and
a respective lowest unoccupied molecular orbital (LUMO) is energetically higher for all organic materials (Ci) than a respective lowest unoccupied molecular orbital (LUMO) of the organic material (A) or of the at least one further organic material (B).

3. The device according to claim 2, wherein the following applies for one or more organic materials (Ci; i≧1) from which the exciton-separating layer (ESL) is formed and for the organic material (A) and the at least one further organic material (B) from which the exciton-harvesting layer (EHL) is formed:
for at least one of the organic materials (Ci) a lowest unoccupied molecular orbital (LUMO) is energetically lower than a respective lowest unoccupied molecular orbital (LUMO) of the organic material (A) and of the at least one further organic material (B); and
a respective highest occupied molecular orbital (HOMO) is energetically lower for all organic materials (Ci) than a respective highest occupied molecular orbital (HOMO) of the organic material (A) or of the at least one further organic material (B).

4. The device according to claim 1, wherein a mass concentration of the organic material (A) in the exciton-harvesting layer (EHL) produced as mixed layer is greater than approximately 30%, preferably greater than approximately 60% and more preferably greater than approximately 90%.

5. The device according to claim 4, wherein the lowest unoccupied molecular orbital (LUMO) of the organic material (A) is energetically lower or at the most approximately 0.1 eV higher that the lowest unoccupied molecular orbital (LUMO) of the at least one further organic material (B).

6. The device according to claim 4, wherein the highest occupied molecular orbital (HOMO) of the organic material (A) is energetically higher or at the most approximately 0.1 eV lower than the highest occupied molecular orbital (HOMO) of the at least one further organic material (B).

7. The device according to claim 1, wherein a mass concentration of the organic material (A) as well as a mass concentration of the further organic material (B) in the exciton-harvesting layer (EHL) produced as a mixed layer is greater than approximately 15%, preferably greater than approximately 30%.

8. The device according to claim 7, wherein a lowest unoccupied molecular orbital (LUMO) of the organic material (B) is energetically lower or at the most approximately 0.1 eV higher than the lowest unoccupied molecular orbital (LUMO) of the organic material (A).

9. The device according to claim 7, wherein a highest occupied molecular orbital (HOMO) of the at least one further organic material (B) is energetically higher or at the most approximately 0.1 eV lower than the highest occupied molecular orbital (HOMO) of the organic material (A).

10. The device according to claim 1, wherein a triplet transport layer (TTL) of one or several organic materials is arranged between the exciton-harvesting layer (EHL) and the exciton-separating layer (ESL), the energy of a lowest triplet excitation state of the triplet transport layer being less than or equal to the energy of the lowest triplet excitation state of the organic material (A) in the exciton-harvesting layer (EHL) produced as mixed layer.

11. The device according to claim 10, wherein a highest occupied molecular orbital (HOMO) of the triplet transport layer (TTL) is energetically equal to or is lower than the respective highest occupied molecular orbital (HOMO) of the organic material (A) or of the at least one further organic material in the exciton-harvesting layer (EHL) produced as mixed layer.

12. The device according to claim 10, wherein a lowest unoccupied molecular orbital (LUMO) of the triplet transport layer (TTL) is energetically equal to or is higher than the lowest unoccupied molecular orbital (LUMO) of the organic material (A) or of the at least one further organic material in the exciton-harvesting layer (EHL) produced as mixed layer.

13. The device according to claim 1, wherein in the at least one further organic material (B) an energy difference between the lowest singlet excitation state for excitons (S₁^{B}) and the lowest triplet excitation state for excitons (T₁^{B}) is less than approximately 0.5 eV, preferably less than approximately 0.3 eV.

14. The device according to claim 1, wherein the at least one further organic material (B) is from one of the following material classes:
fullerene or carbon nanotubes, in particular C₆₀, C₇₀ or C₈₄ and their derivatives;
metallo-organic compounds, in particular those whose lowest excitation state comprises at least partially an excitation of an electron from the metal to the ligand (MLCT—metal-to-ligand charge transfer) or from the ligand to the metal (LMCT—ligand-to-metal charge transfer); and
phosphorescent materials with a phosphorescence quantum yield greater than approximately 0.1%, preferably greater than approximately 1% in dilute solution.

15. The device according to claim 14, wherein the metallo-organic compound comprises a heavy metal with an atomic number greater than 21, preferably greater than 39.

16. The device according to claim 14, wherein the metallo-organic compound comprises a metal from the following group of metals: Ru, Pd, Ag, Cd, In, Sn, Ta, W, Re, Os, Ir, Pt, Au, Hg, Ti, Pb, La, Ce, Pr, Nd, Sm, Eu, Gd, Th, Er, Tm, Yb or Lu, preferably Ru, Rh, Re, Os, Ir or Pt.

17. The device according to claim 1, wherein the organic material (A) in the exciton-harvesting layer (EHL) produced as mixed layer is an oligothiophene derivative, a perylene derivative, especially a derivative of perylene tetracarboxylic acid dianhydride, perylene tetracarboxylic acid diimide or perylene tetracarboxylic acid bisimidazole, or a phthalocyanine.

18. The device according to claim 1, wherein the exciton-separating layer (ESL) is formed as a light-absorbing layer producing singlet and/or triplet excitation states, in which produced singlet and/or triplet excitation states diffuse to the interface between the exciton-harvesting layer (EHL) and the exciton-separating layer (ESL), where they can be converted into charge carrier pairs.

19. The device according to claim 1, wherein the exciton-separating layer (ESL) is a mixed layer containing several organic materials, in which:
a lowest singlet excitation state for excitons of one of the several organic materials is energetically higher than a lowest singlet excitation state for excitons of a further one of the several organic materials;
the further organic material is formed in such a manner that it converts singlet excitons into triplet excitons with a quantum yield of at least 20%, preferably at least 50% by means of an ISC mechanism (ISC—Inter-System-Crossing);
a lowest triplet excitation state for excitons of the further organic material is energetically higher than a lowest triplet excitation state for excitons of the one organic material.

20. The device according to claim 19, wherein a photoactive donor-acceptor bulk-heterojunction is formed in the exciton-separating layer (ESL) produced as mixed layer by means of the one organic material and of the at least one further organic material.

21. The device according to claim 1, wherein a interface of the exciton-harvesting layer (EHL), that faces away from the interface with the exciton-separating layer (ESL)/the triplet transport layer (TTL), is a triplet blocking layer (TBL) in which energetically lowest energetic triplet excitation states are energetically higher than lowest energetic triplet excitation states in the exciton-harvesting layer (EHL).

22. The device according to claim 1, wherein the contact and/or the countercontact are semi-transparent or transparent.

23. The device according to claim 1, wherein a p-doped layer (M-i-p device) is arranged between the contact and the photoactive region.

24. The device according to claim 1, wherein an n-doped layer (M-i-n device or n-i-p device) is arranged between the contact and the photoactive region.

25. The device according to claim 1, wherein one or more layers in the organic region have been deposited by thermal vaporization in a high vacuum or the vaporizing of organic materials into an inert carrier gas that transports the organic materials to a substrate (organic vapor phase deposition).

26. The device according to claim 1, wherein one or more layers in the organic region have been deposited from a liquid solution, especially by spin-coating, application with a doctor blade and/or printing.

27. The device according to claim 1, wherein the exciton-harvesting layer (EHL) has a thickness between approximately 5 nm and approximately 200 nm.

28. The device according to claim 1, wherein the exciton-harvesting layer (EHL), the exciton-separating layer (ESL) and/or the triplet transport layer (TTL) are formed from a donor-acceptor-donor oligomer or from an acceptor-donor-acceptor oligomer.

29. An arrangement with at least two device according to claim 1, wherein the at least two devices are stacked on each other.
